(19) United States
(12) Patent Application Publication
(10) Pub. No.: US 2006/0255449 A1
(43) Pub. Date: Nov. 16, 2006

(54) Lid used in package structure and the package structure having the same

(76) Inventors: Yonggill Lee, Kaoshiung (TW); Kyungsoo Rho, Kaoshiung (TW); Taejun Jeong, Kaoshiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/354,177

(22) Filed: Feb. 15, 2006

(30) Foreign Application Priority Data
May 12, 2005 (TW) 094115445

(51) Int. Cl. H01L 23/04; H01L 23/52; H01L 23/24; H01L 23/02; H01L 23/495

(52) U.S. Cl. 257/698; 257/687; 257/686; 257/777; 257/676

(57) ABSTRACT

The present invention relates to a lid and a package structure having the same. The package structure comprises a first substrate, a first chip, a lid and a second package. The first chip is disposed on and electrically connected to the top surface of the first substrate. The lid is disposed on the top surface of the first substrate and comprises a body, a plurality of through holes and a cavity. The through holes penetrate the body and have a conductive material therein. The cavity accommodates the first chip. The second package is on the lid and is electrically connected to the first substrate through the conductive material in the through holes. As a result, the amount of the signal path between the second package and the first substrate is increased, and the manufacturing cost of the package structure is low.

### BACKGROUND OF THE INVENTION

1. Field of the Invention

The present invention relates to a stacked semiconductor package structure, particularly to a stacked semiconductor package structure having a lid.

2. Description of the Related Art

FIG. 1 shows a cross-sectional view of a first type of a conventional stacked package structure. The conventional stacked package structure 1 comprises a first package 10, a second package 20, a plurality of first solder balls 15 and a plurality of second solder balls 25.

The first package 10 comprises a first substrate 11, a first chip 12, a first molding compound 13 and a plurality of first wires 14. The first substrate 11 has a top surface 111 and a bottom surface 112, wherein the top surface 111 has a plurality of pads 113, and the bottom surface 112 has the first solder balls 15. The first chip 12 is adhered to the top surface 111 of the first substrate 11, and is electrically connected to the top surface 111 of the first substrate 11 by utilizing the first wires 14. The first molding compound 13 encapsulates the first chip 12, the first wires 14 and part of the top surface 111 of the first substrate 11.

The second package 20 comprises a second substrate 21, a second chip 22, a second molding compound 23 and a plurality of second wires 24. The second substrate 21 has a top surface 211 and a bottom surface 212, wherein the bottom surface 212 has the second solder balls 25. The second chip 22 is adhered to the top surface 211 of the second substrate 21, and is electrically connected to the top surface 211 of the second substrate 21 by utilizing the second wires 24. The second molding compound 23 encapsulates the second chip 22, the second wires 24 and part of the top surface 211 of the second substrate 21.

In the conventional stacked package structure 1, the second package 20 is stacked above the first package 10, and the second solder balls 25 are connected to the pads 113 so that the second substrate 21 can be electrically connected to the first substrate 11. That is, the signal path between the first package 10 and the second package 20 is the second solder balls 25. However, because the second solder balls 25 must be higher than the first molding compound 13 and are in spherical appearance, their volume are always relative large. Thus, the amount of the second solder balls 25 is limited. As a result, the amount of the signal path between the first package 10 and the second package 20 is reduced.

FIG. 2 shows a cross-sectional view of a second type of a conventional stacked package structure. In order to solve the above-mentioned shortcoming, another type of conventional stacked package structure 2 is provided, as shown in FIG. 2. The difference between the package structure 1 of FIG. 1 and the package structure 2 is an interposer 28 added in the package structure 2. The interposer 28 has a top surface 281 and a bottom surface 282, wherein the top surface 281 has a plurality of upper pads 283, and the bottom surface 282 has a plurality of lower pads 284. Additionally, the second solder balls 25 in the package structure 1 are replaced by a plurality of third solder balls 26 and fourth solder balls 27, wherein the third solder balls 26 are used for connecting the bottom surface 212 of the second substrate 21 and the upper pads 283, and the fourth solder balls 27 are used for connecting the top surface 111 of the first substrate 11 and the lower pads 284.

In the package structure 2, the signal path between the first package 10 and the second package 20 is the third solder balls 26, the interposer 28 and the fourth solder balls 27. Although the volumes of the third solder balls 26 and the fourth solder balls 27 are reduced, the difficulty of aligning the interposer 28 during manufacture process will increase the manufacture cost of the package structure 2.

Consequently, there is an existing need for a novel and improved stacked package structure to solve the above-mentioned problems.

### SUMMARY OF THE INVENTION

One objective of the present invention is to provide a package structure having a lid that is used as the signal path between the upper substrate and the lower substrate. As a result, the amount of the signal path between the two substrates is increased, and the manufacturing cost of the package structure is low.

Another objective of the present invention is to provide a lid used in a package structure comprising a body, a plurality of through holes, a cavity, a plurality of first conductive elements and a plurality of second conductive elements. The body has a first surface and a second surface opposite to the first surface. The through holes penetrate the body, and have a plurality of first openings on the first surface and a plurality of second openings on the second surface. Each through hole has a conductive material therein. The cavity has an opening on the second surface. The first conductive elements are disposed on the first openings. The second conductive elements are disposed on the second openings.

Another objective of the present invention is to provide a stacked package structure comprising a first substrate, a first chip, a lid and a second package. The first substrate has a top surface and a bottom surface. The first chip is disposed on the top surface of the first substrate and electrically connected to the top surface. The lid is disposed on the top surface of the first substrate, and comprises a body, a plurality of through holes and a cavity. The body has a first surface and a second surface opposite to the first surface. The through holes penetrate the body, and have a plurality of first openings on the first surface and a plurality of second openings on the second surface. Each through holes has a conductive material therein. The cavity has an opening on the second surface for accommodating the first chip. The second package is disposed above the lid, wherein the lid is electrically connected to the first substrate through the conductive material in the through holes.

### BRIEF DESCRIPTION OF THE DRAWINGS

FIG. 1 shows a cross-sectional view of a first type of a conventional stacked package structure;

FIG. 2 shows a cross-sectional view of a second type of a conventional stacked package structure;

FIG. 3a shows a cross sectional view of a first type of lid used in a package structure according to the present invention;

FIG. 3b shows a bottom view of a first type of lid used in a package structure according to the present invention;

FIG. 3c shows a top view of a first type of lid used in a package structure according to the present invention;

FIG. 4a shows a cross sectional view of a second type of lid used in a package structure according to the present invention;

FIG. 4b shows a bottom view of a second type of lid used in a package structure according to the present invention;

FIG. 4c shows a top view of a second type of lid used in a package structure according to the present invention;

FIG. 5 shows a stacked package structure according to a first embodiment of the present invention;

FIG. 6 shows a stacked package structure according to a second embodiment of the present invention;

FIG. 7 shows a stacked package structure according to a third embodiment of the present invention;

FIG. 8 shows a stacked package structure according to a fourth embodiment of the present invention; and

FIG. 9 shows a stacked package structure according to a fifth embodiment of the present invention.

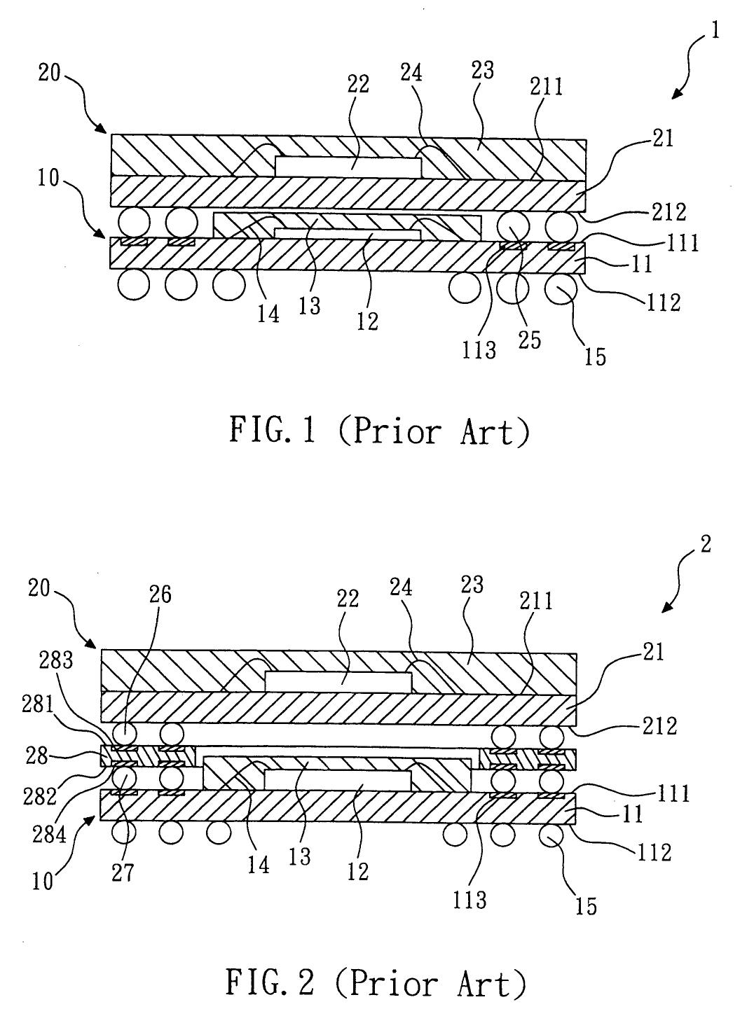

### DETAILED DESCRIPTION OF THE INVENTION

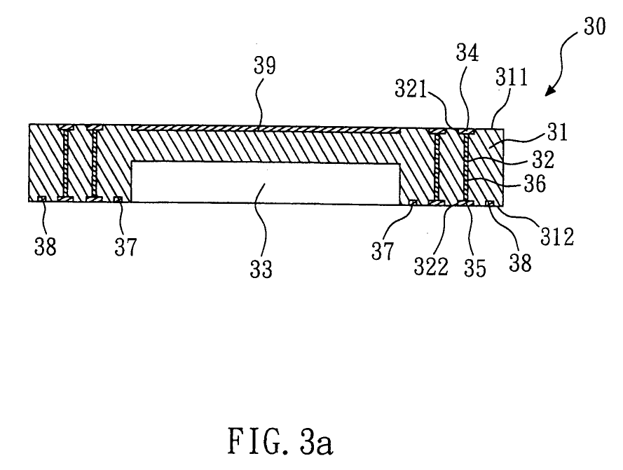

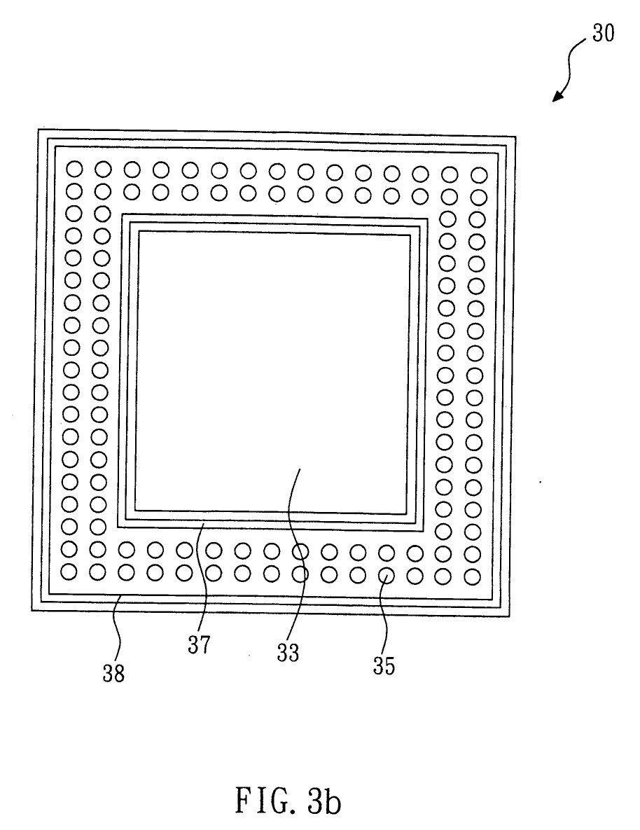

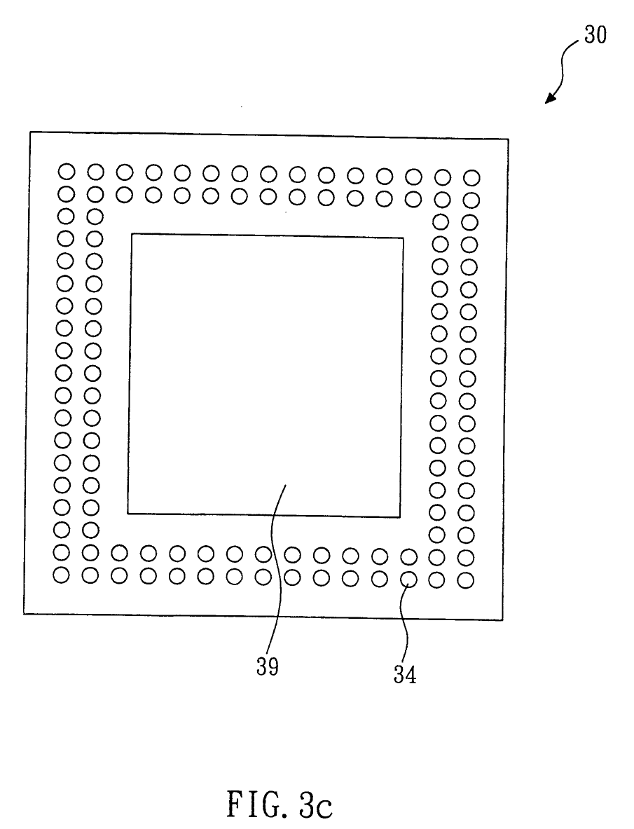

FIGS. 3a to 3c show a first type of lid used in a package structure according to the present invention, wherein FIG. 3a is a cross sectional view, FIG. 3b is a bottom view, and FIG. 3c is a top view. The lid 30 comprises a body 31, a plurality of through holes 32, a cavity 33, a plurality of first conductive elements 34, a plurality of second conductive elements 35, an inner metal line 37, an outer metal line 38 and a shield metal layer 39.

The body 31 has a first surface 311 and a second surface 312 opposite to the first surface 311. The through holes 32 penetrate the body 31, and have a plurality of first openings 321 on the first surface 311 and a plurality of second openings 322 on the second surface 312. Each through hole 32 has a conductive material 36 (for example, metal) therein. The cavity 33 is a recess hole or blind hole, which has an opening on the second surface 312. The first conductive elements 34, for example, pads or solder balls, are disposed on the first openings 321. The second conductive elements 35, for example, pads or solder balls, are disposed on the second openings 322.

The inner metal line 37 is on the second surface 312, wherein the inner metal line 37 forms a close curve and is disposed between the second conductive elements 35 and the cavity 33. The outer metal line 38 is on the second surface 312, wherein the outer metal line 38 forms a close curve and is disposed outside the second conductive elements 35. The inner metal line 37 and the outer metal line 38 can prevent moisture from entering the cavity 33 when the lid 30 is used in a harsh environment.

The shield metal layer 39 is on the first surface 311, and corresponds to the cavity 33, which can protect the chip in the cavity 33 when the lid 30 is in use. Additionally, the shield metal layer 39 may be replaced by a metal trace layer so as to increase the wiring area on the first surface 311.

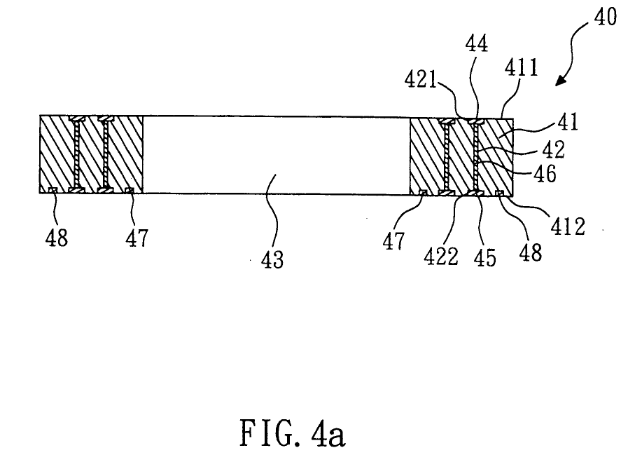

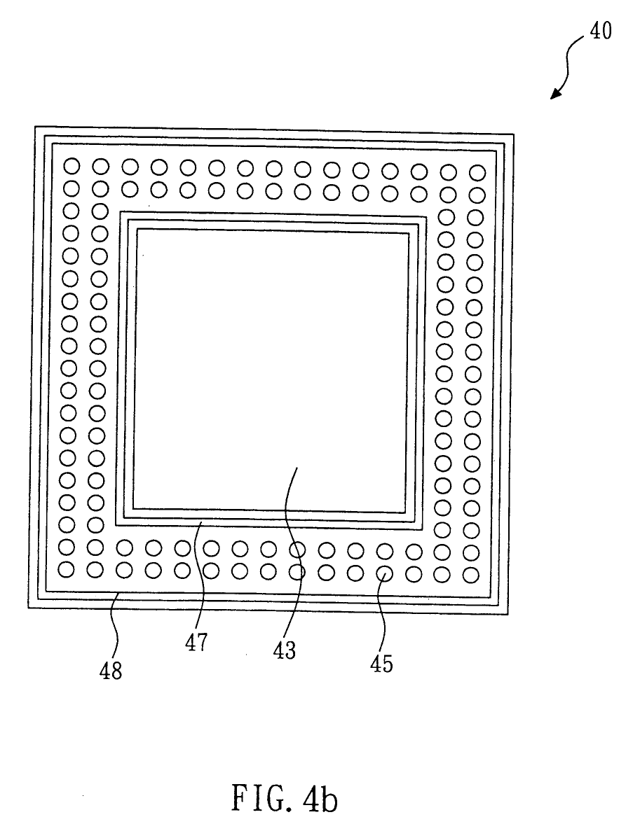

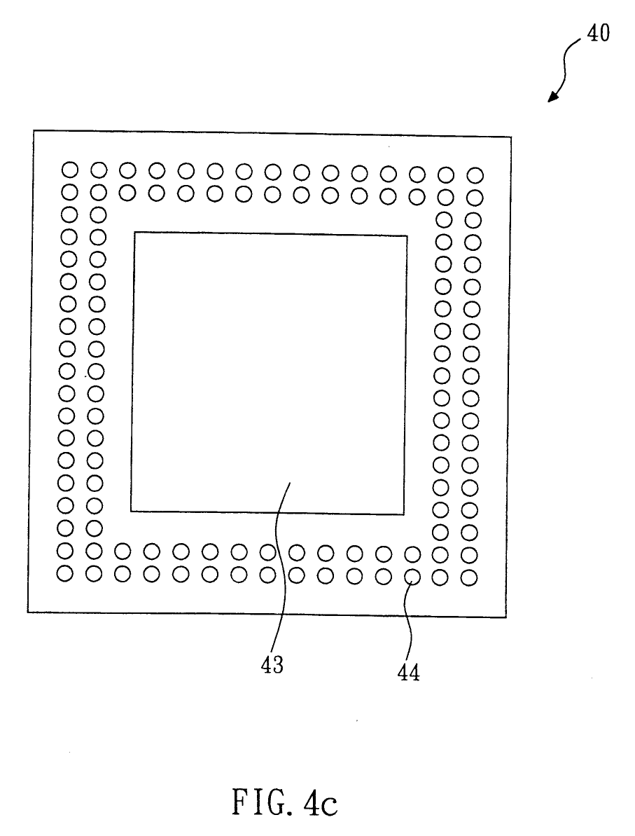

FIGS. 4a to 4c show a second type of lid used in a package structure according to the present invention, wherein FIG. 4a is a cross sectional view, FIG. 4b is a bottom view, and FIG. 4c is a top view. The lid 40 comprises a body 41, a plurality of through holes 42, a cavity 43, a plurality of first conductive elements 44, a plurality of second conductive elements 45, an inner metal line 47 and an outer metal line 48.

The lid 40 is substantially the same as the lid 30 in FIGS. 3a to 3c, except that the cavity 33 in the lid 30 is a recess hole or blind hole that does not penetrate the body 31, but the cavity 43 in the lid 40 is a through hole that penetrates the body 41.

The body 41 has a first surface 411 and a second surface 412 opposite to the first surface 411. The through holes 42 penetrate the body 41, and have a plurality of first openings 421 on the first surface 411 and a plurality of second openings 422 on the second surface 412. Each through hole 42 has a conductive material 46 (for example, metal) therein. The first conductive elements 44, for example, pads or solder balls, are disposed on the first openings 421. The second conductive elements 45, for example, pads or solder balls, are disposed on the second openings 422.

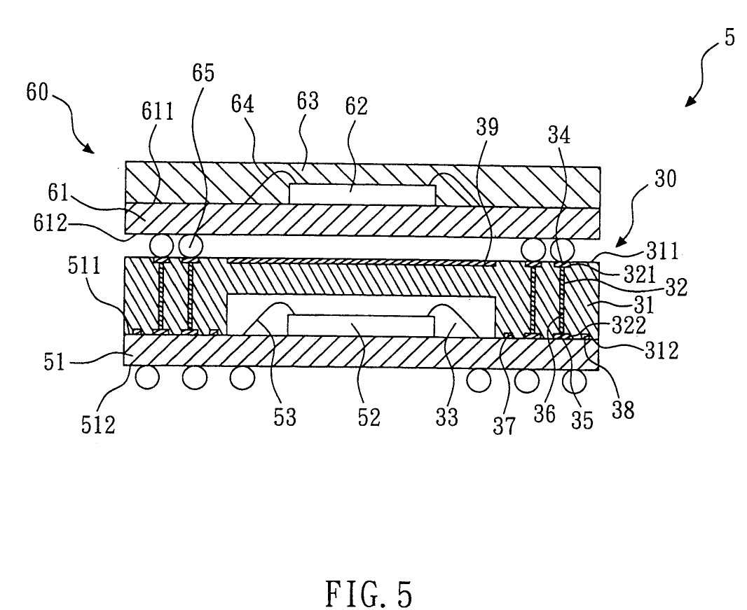

FIG. 5 shows a stacked package structure according to a first embodiment of the present invention. The stacked package structure 5 comprises the lid 30 as shown in FIGS. 3a to 3c. The stacked package structure 5 comprises a first substrate 51, a first chip 52, the lid 30 and a second package 60. The first substrate 51 has a top surface 511 and a bottom surface 512. The first chip 52 is disposed on the top surface 511 of the first substrate 51 and is electrically connected to the top surface 511 by utilizing a plurality of wires 53. It should be noted that the first chip 52 may be electrically connected to the top surface 511 by another method, such as flip chip bonding.

The lid 30 is as shown in FIGS. 3a to 3c, and comprises a body 31, a plurality of through holes 32, a cavity 33, a plurality of first conductive elements 34, a plurality of second conductive elements 35, an inner metal line 37, an outer metal line 38 and a shield metal layer 39.

The body 31 has a first surface 311 and a second surface 312 opposite to the first surface 311. The through holes 32 penetrate the body 31, and have a plurality of first openings 321 on the first surface 311 and a plurality of second openings 322 on the second surface 312. Each through hole 32 contains a conductive material 36 (for example, metal) therein. The cavity 33 is a recess hole or blind hole, which has an opening on the second surface 312. The cavity 33 is used for accommodating the first chip 52. The first conductive elements 34, for example, pads or solder balls, are disposed on the first openings 321. The second conductive elements 35, for example, pads or solder balls, are disposed on the second openings 322.

The inner metal line 37 is on the second surface 312, wherein the inner metal line 37 forms a close curve and is disposed between the second conductive elements 35 and the cavity 33. The outer metal line 38 is on the second surface 312, wherein the outer metal line 38 forms a close curve and is disposed outside the second conductive elements 35. The inner metal line 37 and the outer metal line 38 can prevent moisture from entering the cavity 33 when the lid 30 is used in a harsh environment.

The shield metal layer 39 is on the first surface 311, and corresponds to the cavity 33, which can protect the first chip 52.

In the embodiment, there is no molding compound in the cavity 33. That is, the lid 30 covers the first chip 52 directly. However, it should be noted that the first chip 52 may be encapsulated by a molding compound, and then covered by the lid 30.

In the embodiment, the lid 30 is adhered to the top surface 511 of the first substrate 51 by epoxy so that the second conductive elements 35 on the lid 30 are electrically connected to the electrical points (not shown) on the top surface 511 of the first substrate 51. It should be noted that if there are pads or solder balls on the top surface 511 of the first substrate 51, the pads or solder balls can be welded with the second conductive elements 35. Therefore, no binder is needed.

The second package 60 is disposed above the lid 30, and comprises a second substrate 61, a second chip 62, a second molding compound 63 and a plurality of wires 64. The second substrate 61 has a top surface 611 and a bottom surface 612. The second chip 62 is disposed on the top surface 611 of the second substrate 61 and is electrically connected to the top surface 611 of the second substrate 61 by utilizing the wires 64. It should be noted that the second chip 62 may be electrically connected to the second substrate 61 by another method, such as flip chip bonding. The second molding compound 63 is used for encapsulating the second chip 62 and part of the top surface 611 of the second substrate 61.

The bottom surface 612 of the second substrate 61 has a plurality of third conductive elements 65 (for example, solder balls) that are electrically connected to the first conductive elements 34. Thus, in the stacked package structure 5, the signal path between the second package 60 and the first substrate 51 is the third conductive elements 65, the first conductive elements 34, the conductive material 36 and the second conductive elements 35. As a result, the volumes of the third conductive elements 65 are reduced hugely.

It is to be understood that the second package 60 may be another type of any conventional package.

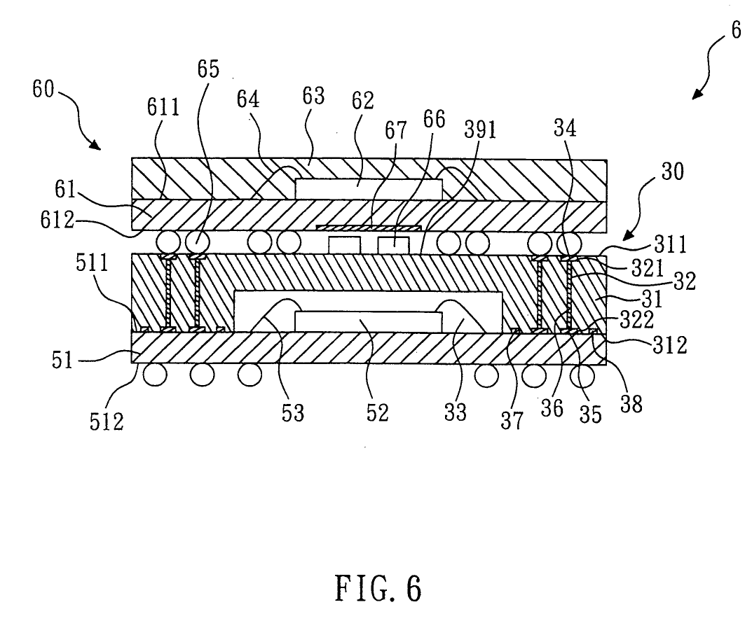

FIG. 6 shows a stacked package structure according to a second embodiment of the present invention. The stacked package structure 6 of the embodiment is substantially the same as the stacked package structure 5 of the first embodiment, except that the shield metal layer 39 of the first embodiment is replaced by a metal trace layer 391 so as to increase the wiring area on the first surface 311. Additionally, if necessary, a plurality of passive elements 66 are disposed on the metal trace layer 391, and a shield metal layer 67 is disposed on the bottom surface 612 of the second substrate 61, wherein the shield metal layer 67 corresponds to the passive elements 66.

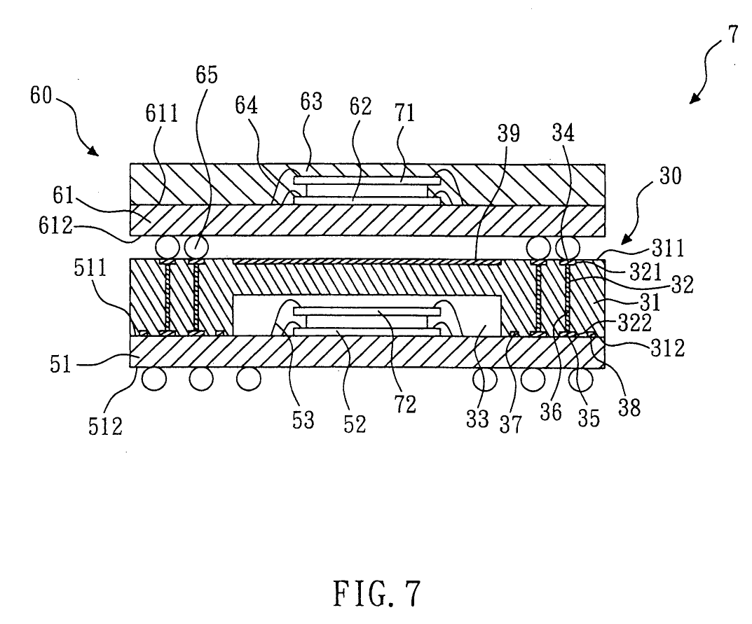

FIG. 7 shows a stacked package structure according to a third embodiment of the present invention. The stacked package structure 7 of the embodiment is substantially the same as the stacked package structure 5 of the first embodiment, except that the stacked package structure 7 of the embodiment further has a third chip 71 and a fourth chip 72.

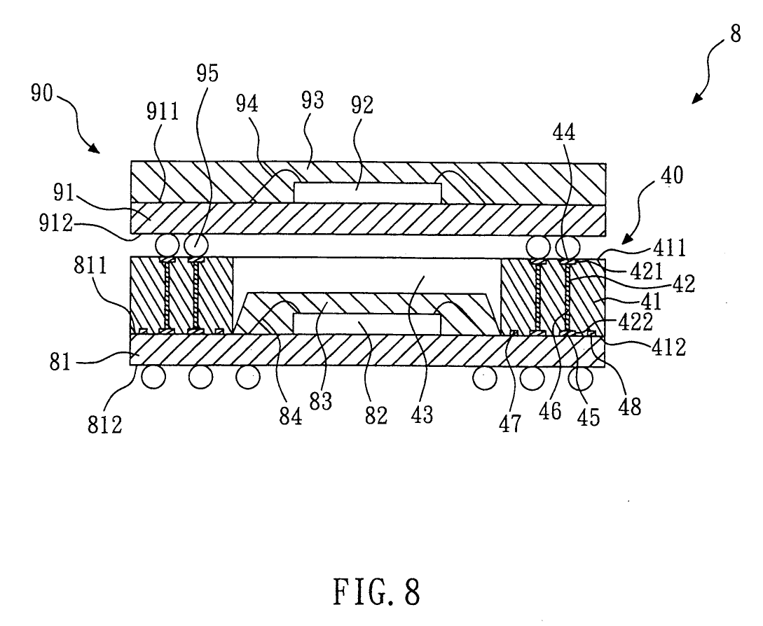

FIG. 8 shows a stacked package structure according to a fourth embodiment of the present invention. The stacked package structure 8 comprises the lid 40 as shown in FIGS. 4a to 4c. The stacked package structure 8 comprises a first substrate 81, a first chip 82, the lid 40, a first molding compound 83 and a second package 90. The first substrate 81 has a top surface 811 and a bottom surface 812. The first chip 82 is disposed on the top surface 811 of the first substrate 81 and is electrically connected to the top surface 811 by utilizing a plurality of wires 84. It should be noted that the first chip 82 may be electrically connected to the first substrate 81 by another method, such as flip chip bonding.

The lid 40 is as shown in FIGS. 4a to 4c, and comprises a body 41, a plurality of through holes 42, a cavity 43, a plurality of first conductive elements 44, a plurality of second conductive elements 45, an inner metal line 47 and an outer metal line 48.

The body 41 has a first surface 411 and a second surface 412 opposite to the first surface 411. The cavity 43 penetrates the body 41, which is used for accommodating the first chip 82. The through holes 42 penetrate the body 41, and have a plurality of first openings 421 on the first surface 411 and a plurality of second openings 422 on the second surface 412. Each through hole 42 has a conductive material 46 (for example, metal) therein. The first conductive elements 44, for example, pads or solder balls, are disposed on the first openings 421. The second conductive elements 45, for example, pads or solder balls, are disposed on the second openings 422.

In the embodiment, the lid 40 does not cover the first chip 82 completely. Therefore, the first chip 82 needs to be encapsulated by the first molding compound 83, and then the lid 40 is attached to the first substrate 81.

In the embodiment, the lid 40 is adhered to the top surface 811 of the first substrate 81 by epoxy so that the second conductive elements 45 on the lid 40 are electrically connected to the electrical points (not shown) on the top surface 811 of the first substrate 81. It should be noted that if there are pads or solder balls on the top surface 811 of the first substrate 81, the pads or solder balls can be welded with the second conductive elements 45. Therefore, no binder is needed.

The second package 90 is disposed above the lid 0, and comprises a second substrate 91, a second chip 92, a second molding compound 93 and a plurality of wires 94. The second substrate 91 has a top surface 911 and a bottom surface 912. The second chip 92 is disposed on the top surface 911 of the second substrate 91 and is electrically connected to the top surface 911 by utilizing the wires 94. It should be noted that the second chip 92 may be electrically connected to the second substrate 91 by other method, such as flip chip bonding. The second molding compound 93 is used for encapsulating the second chip 92 and part of the top surface 911 of the second substrate 91.

The bottom surface 912 of the second substrate 91 has a plurality of third conductive elements 95 (for example, solder balls) that are electrically connected to the first conductive elements 44. Thus, in the stacked package structure 8, the signal path between the second package 90 and the first substrate 81 is the third conductive elements 95, the first conductive elements 44, the conductive material 46 and the second conductive elements 45.

It is to be understood that the second package 90 may be another type of any conventional package.

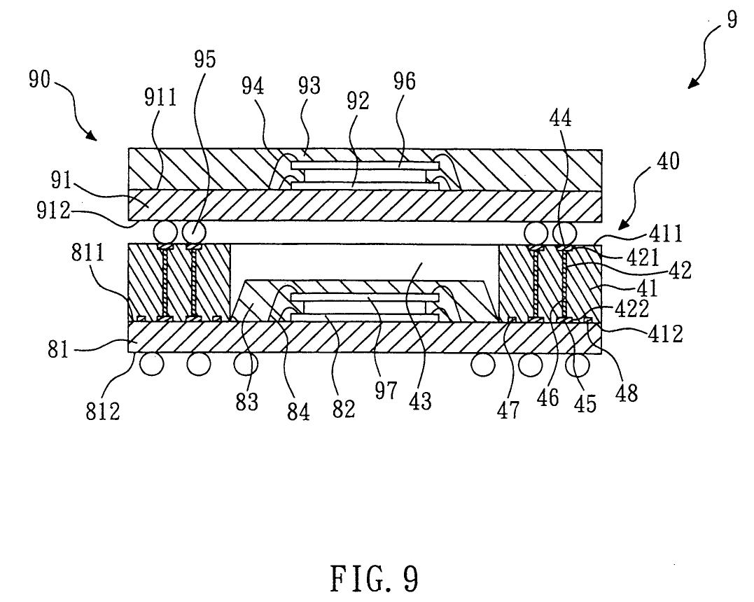

FIG. 9 shows a stacked package structure according to a fifth embodiment of the present invention. The stacked package structure 9 of the embodiment is substantially the same as the stacked package structure 8 of the fourth embodiment, except that the stacked package structure 9 of the embodiment further has a third chip 96 and a fourth chip 97.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A lid used in a package structure, the lid comprising:
a body having a first surface and a second surface opposite to the first surface;
a plurality of through holes penetrating the body, and having a plurality of first openings on the first surface and a plurality of second openings on the second surface, the through holes having a conductive material therein;
a cavity having an opening on the second surface;
a plurality of first conductive elements disposed on the first openings; and
a plurality of second conductive elements disposed on the second openings.

2. The lid according to claim 1, wherein the first conductive elements and the second conductive elements are pads.

3. The lid according to claim 1, wherein the first conductive elements and the second conductive elements are solder balls.

4. The lid according to claim 1, further comprising an inner metal line disposed on the second surface, wherein the inner metal line forms a close curve and is disposed between the second conductive elements and the cavity.

5. The lid according to claim 1, further comprising an outer metal line disposed on the second surface, wherein the outer metal line forms a close curve and is disposed outside the second conductive elements.

6. The lid according to claim 1, further comprising a shield metal layer disposed on the first surface, wherein the shield metal layer corresponds to the cavity.

7. The lid according to claim 1, wherein the cavity is a recess hole.

8. The lid according to claim 1, wherein the cavity penetrates the body.

9. The lid according to claim 1, further comprising a metal trace layer on the first surface.

10. A stacked package structure comprising:
a first substrate having a top surface and a bottom surface;
a first chip disposed on the top surface of the first substrate and electrically connected to the top surface;
a lid disposed on the top surface of the first substrate, the lid comprising:
a body having a first surface and a second surface opposite to the first surface;
a plurality of through holes penetrating the body, and having a plurality of first openings on the first surface and a plurality of second openings on the second surface, the through holes having a conductive material therein; and
a cavity having an opening on the second surface for accommodating the first chip; and
a second package disposed above the lid, the lid electrically connected to the first substrate through the conductive material in the through holes.

11. The stacked package structure according to claim 10, wherein the lid further comprises a plurality of first conductive elements disposed on the first openings, and the second package electrically connected to the first conductive elements.

12. The stacked package structure according to claim 10, wherein the lid further comprises a plurality of second conductive elements disposed on the second openings, and the second conductive elements electrically connected to the top surface of the first substrate.

13. The stacked package structure according to claim 12, wherein the lid further comprises an inner metal line disposed on the second surface, the inner metal line forming a close curve and disposed between the second conductive elements and the cavity.

14. The stacked package structure according to claim 12, wherein the lid further comprises an outer metal line disposed on the second surface, the outer metal line forming a close curve and disposed outside the second conductive elements.

15. The stacked package structure according to claim 10, wherein the lid further comprises a shield metal layer on the first surface, the shield metal layer corresponding to the cavity.

16. The stacked package structure according to claim 10, wherein the cavity is a recess hole.

17. The stacked package structure according to claim 10, wherein the cavity penetrates the body.

18. The stacked package structure according to claim 17, further comprising a first molding compound for encapsulating the first chip and part of the top surface of the first substrate.

19. The stacked package structure according to claim 10, wherein the lid further comprises a metal trace layer on the first surface, and the metal trace layer electrically connected to the second package.

20. The stacked package structure according to claim 10, wherein the second package comprises:
a second substrate having a top surface and a bottom surface;
a second chip disposed on the top surface of the second substrate and electrically connected to the top surface of the second substrate; and
a second molding compound used for encapsulating the second chip and part of the top surface of the second substrate.

21. The stacked package structure according to claim 10, further comprising a plurality of passive elements disposed on the first surface of the body of the lid.

22. The stacked package structure according to claim 21, wherein the second substrate further comprises a shield metal layer disposed on the bottom surface thereof, the shield metal layer corresponding to the passive elements.
